(19) United States
(12) Patent Application Publication
(10) Pub. No.: US 2006/0188826 A1
(43) Pub. Date: Aug. 24, 2006

(54) Method for utilizing dry film

(76) Inventors: Tsung-Yen Tseng, Pingtung County (TW); Min-Lung Huang, Kaohsiung City (TW); Chi-Iong Tsai, Kaohsiung City (TW); Min-Chih Yang, Kaohsiung County (TW)

Correspondence Address: HARNESS, DICKEY & PIERCE, P.L.C., P.O. BOX 8910, RESTON, VA, 20195, US

(21) Appl. No.: 11/359,582

(22) Filed: Feb. 23, 2006

(30) Foreign Application Priority Data
Feb. 23, 2005 (TW) 094105479

(51) Int. Cl. G03F 7/00

(52) U.S. Cl. 430/322; 430/329

(57) ABSTRACT

A method for utilizing a dry film is provided. A dry film is pressed onto a substrate, such as a wafer. The dry film includes a photoresist layer tightly attached to the substrate and an exposed carrier film with light transmission. Before exposure and development, the carrier film of the dry film is cleaned in a darkroom, wherein the cleaning method may include a step of chemical spraying and a step of rinsing through DI water. Accordingly, the contaminant on the carrier film can be removed. In addition, the dry film burrs can be also removed. Thus, an excellent production yield for sequent exposure and development can be achieved.

### CROSS-REFERENCE TO RELATED APPLICATIONS

This non-provisional application claims priority under 35 U.S.C. § 119(a) on Patent Application No. 094105479 filed in Taiwan, R.O.C. on Feb. 23, 2005, the entire contents of which are hereby incorporated by reference.

### BACKGROUND OF THE INVENTION

1. Field of Invention

The present invention relates to a method for utilizing a dry film, and particularly, to an application method for pressing a dry film onto a substrate, such as a wafer, during a wafer level packaging process.

2. Related Art

In the domain of the wafer level packaging, an image transfer is usually performed through photoresist materials for forming bumps or circuits on a wafer by depositing or etching. In order to achieve a suitable thickness and a favorable image effect, the currently employed photoresist material is dry films. The conventional dry film has a three-layer structure, comprising a carrier film with light transmission, at least one photoresist layer, and a passivation layer, wherein the photoresist layer is sandwiched between the carrier film and the passivation layer. After the passivation layer is peeled off, the photoresist layer of the dry film is pressed onto a substrate, such as a wafer, to be exposed and developed, thereby forming patterned images. However, when the dry film is pressed onto the wafer, the contaminant produced during the process may cause the inaccurate exposure and degrade the production yield.

With reference to FIG. 1, in the wafer level packaging process, when a dry film 10 is pressed onto a wafer 20 or a packaged substrate, a photoresist layer 11, such as the acrylic photosensitive resin, in the dry film 10 is attached to an active area 21 of the wafer 20, and a carrier film 12 with light transmission of the dry film 10 is covered on the photoresist layer 11. In the step of exposure, a mask 30 is disposed above the wafer 20 and the dry film 10, and an exposure beam 31, such as ultraviolet light, passes through the mask 30 and then the carrier film 12, and finally reaches the photoresist layer 11, such that a photochemical reaction occurs on the irradiated part of the photoresist layer 11. When the photoresist layer 11 is a positive photoresist, the irradiated part will be removed after development. When the photoresist layer 11 is a negative photoresist, the irradiated part will be remained after development. Therefore, the sequent production yield depends on the quality of the exposure. However, before the exposure, contaminant, such as residual photoresist 13 and particles 14, may be remained on the carrier film 12 of the dry film 10. Due to the residual photoresist 13 and the particles 14, the exposure beam 31 may be refracted or scattered, leading to inaccurate exposure. Furthermore, dry film burrs 15 appear around the dry film 10 after the dry film 10 has been pressed and cut, which also influences the quality of exposure.

### SUMMARY OF THE INVENTION

One object of the present invention is to provide a method for utilizing a dry film. After a dry film is pressed onto a substrate and before the exposure, a carrier film with light transmission of the dry film is cleaned in a darkroom for removing the contaminant, such as residual photoresist and particles, on the carrier film. At the same time, the dry film burrs around the dry film may be removed. Thereby, an accurate exposure and an excellent sequent production yield are achieved.

Another object of the present invention is to provide a method for forming a photoresist on a wafer. In the method, a carrier film with light transmission is formed on a photoresist layer on an active area of a wafer, and thus the photoresist layer is protected from being removed when the carrier film and the wafer are cleaned.

A further object of the present invention is to provide a flow process for cleaning a dry film pressed on a wafer. The flow process comprises performing a step of chemical spraying for removing the residual photoresist and particles on the carrier film; performing a step of rinsing through de-ionized (DI) water for removing chemical solution; and performing a step of drying for removing the DI water, thereby achieving a sufficient cleaning.

According to the method for utilizing a dry film provided by the present invention, it comprises providing a dry film at least comprising a carrier film with light transmission and a photoresist layer. The film is pressed onto a substrate, such as a wafer, such that the photoresist layer is attached to the substrate. The carrier film of the dry film is cleaned in a darkroom for facilitating the sequent exposure and development. Generally, before the carrier film is cleaned, the dry film is firstly cut to a size corresponding to that of the substrate. The carrier film is cleaned for removing the contaminant, such as residual photoresist and particles, on the carrier film, and the dry film burrs on the edge of the dry film is removed simultaneously. Furthermore, in an embodiment, the step of cleaning the carrier film further includes chemical spraying, water rinsing, drying, and the like. And after the step of cleaning the carrier film, the edge of the photoresist layer of the dry film will shrink.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and thus are not limitative of the present invention, and wherein:

FIG. 1 is a sectional schematic view of a conventional wafer during the exposure after a dry film is pressed on and the wafer is cut.

FIGS. 2A to 2H are sectional schematic views of the process of utilizing a dry film on a substrate according to an embodiment of the present invention.

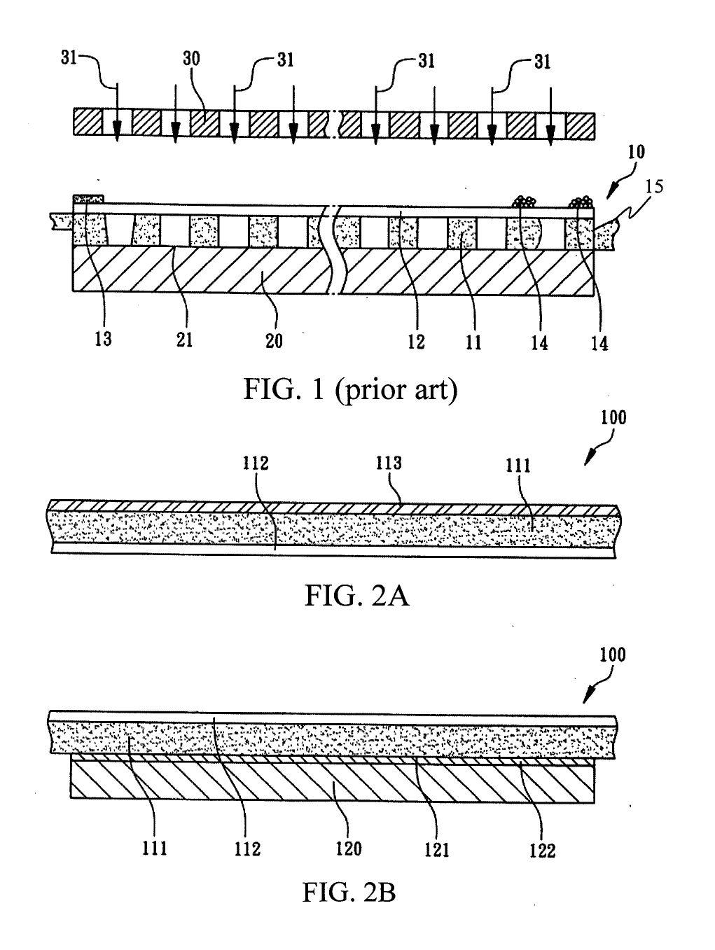

### DETAILED DESCRIPTION OF THE INVENTION

The method for utilizing a dry film provided by the present invention is applicable to a wafer level packaging process, and an embodiment is described below.

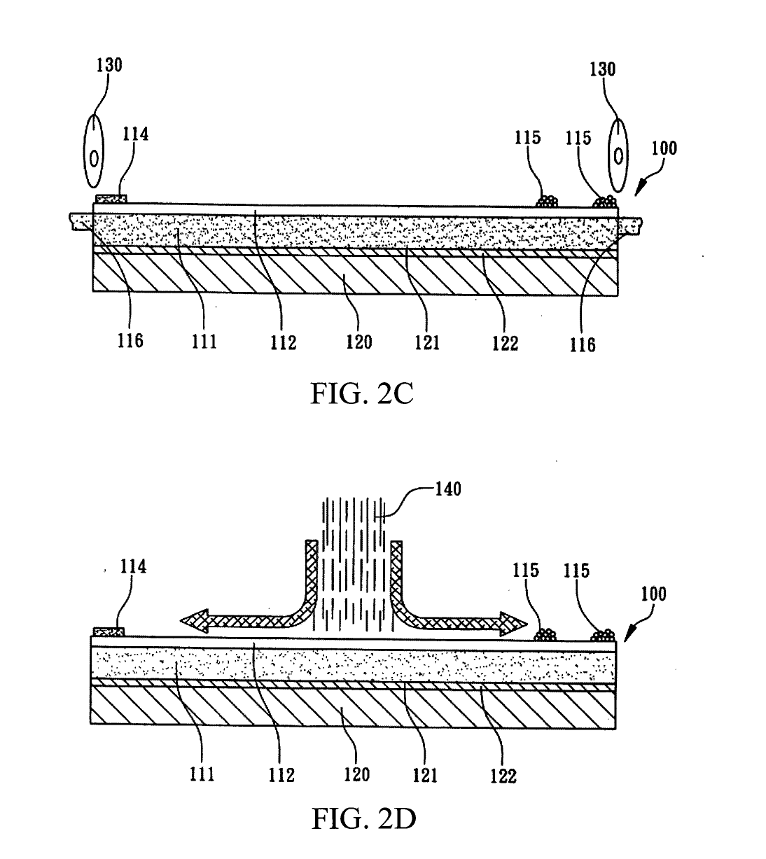

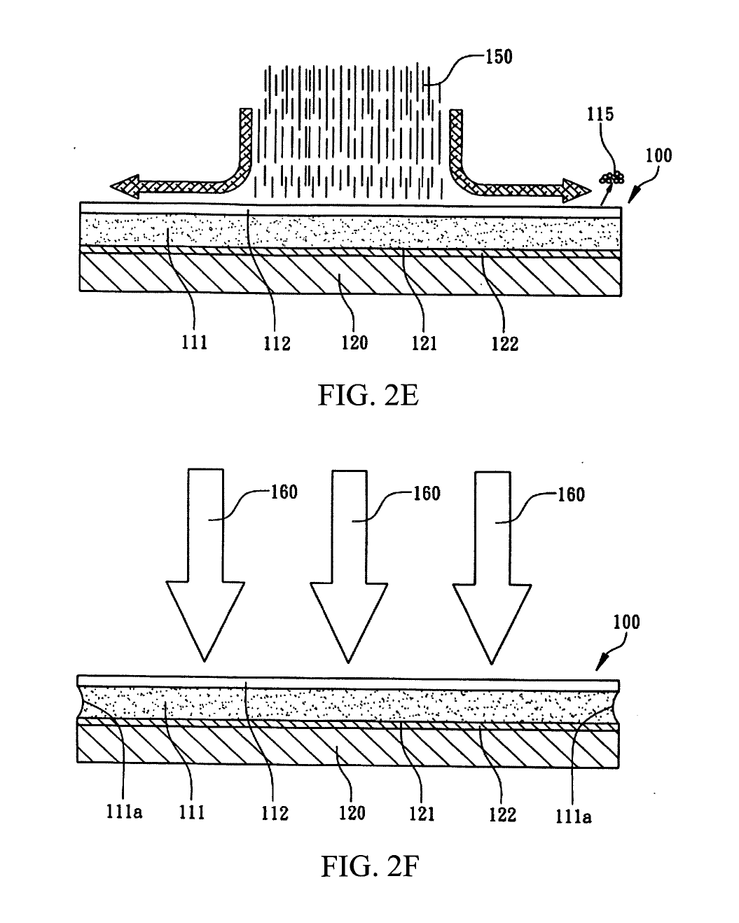

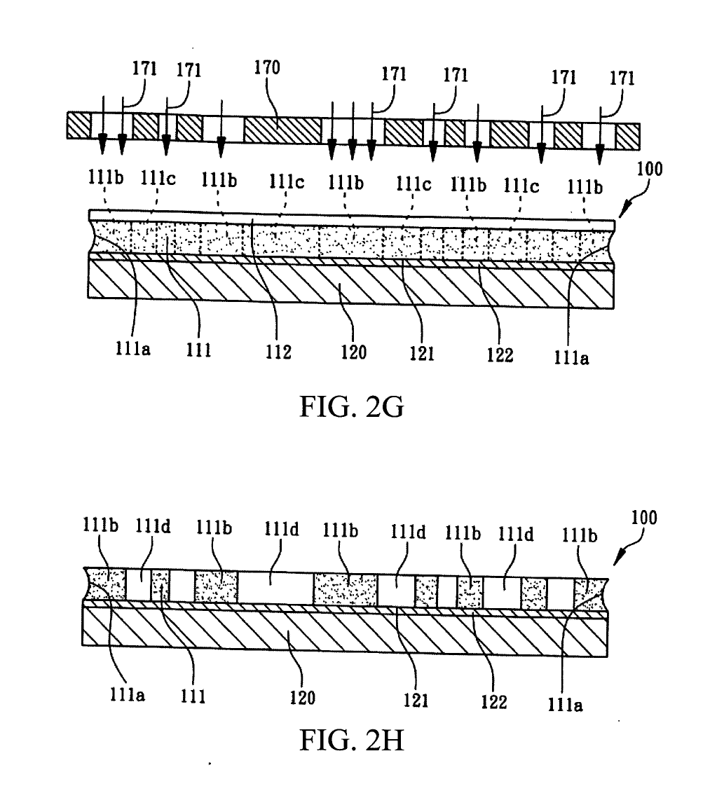

Firstly, with reference to FIG. 2A, a dry film 100 is provided. The dry film 100 comprises at least three layers, namely at least one photoresist layer 111, a carrier film 112 with light transmission, and a passivation film 113. The photoresist layer 111 is a kind of photosensitive resin and may be a positive photoresist or a negative photoresist. The photoresist layer 111 is formed on the carrier film 112 and covered by the passivation film 113. In the present embodiment, the photoresist layer 111 is a negative photoresist as a plating bump. Generally, the material of the carrier film 112 is PET, i.e., polyester, which is also referred to as Mylar film and the material of the passivation film 113 is PE, i.e., polyethylene.

Subsequently, with reference to FIG. 2, the dry film 100 is pressed onto a substrate. In the present embodiment, the substrate which the dry film 100 is pressed onto is a wafer 120. However, the substrate can also be an IC carrier, a printed circuit board (PCB), a ceramic circuit board, and the like. During the process of pressing the dry film, the passivation film 113 is peeled off firstly, and then the photoresist layer 111 of the dry film 100 is attached to an active area 121 of the wafer 120, wherein the dry film 100 may be rolled and attached to the active area 121 through a rolling device (not shown). The carrier film 112 of the dry film 100 is exposed, thereby covering and protecting the photoresist layer 111. In the present embodiment, the wafer 120 is a semiconductor substrate on which an integrated circuit is formed. The wafer 120 has a passivation layer 122 or a molding layer. Alternatively, a redistribution wiring layer (RDL) is formed on the active area 121. Generally, a priming coat (not shown), such as Hexamethyldisilizane (HMDS), is formed on the active area 121 of the wafer 120 in advance for increasing the adhesive force applied to the wafer 120 by the photoresist layer 111.

With reference to FIG. 2C, with a cutting device 130, the dry film 100 is cut to a size corresponding to that of the wafer 120. Generally, after the dry film 100 has been cut, contaminant, such as the residual photoresist 114 or the particles 115, is remained on the exposed surface of the carrier film 112. Furthermore, dry film burrs 116 are also remained on the lateral margin of the photoresist layer 111. The residual photoresist 114, the particles 115, or the dry film burrs 116 all influence the accuracy and quality of the exposure. However, the present invention is not limited to perform the cutting step of the dry film 100. In another embodiment, the dry film 100 may be cut in advance, and then pressed and attached to the wafer 120.

Next, with reference to FIGS. 2D, 2E, and 2F, a cleaning step is performed to remove the residual photoresist 114 or the particles 115 remained after the step of cutting the dry film 100, as well as the dry film burrs 116. The cleaning step is mainly used to clean the carrier film 112, as well as the wafer 120. The cleaning step is performed in a darkroom. That is, the wafer 120 is placed in a darkroom or a yellow room to ensure the optical activity of the photoresist layer 111, such that the inappropriate photochemical reaction of photoresist layer 111 is prevented from occurring. The cleaning step comprises a step of chemical spraying and a step of rinsing through DI water. Preferably, the cleaning step further comprises a step of drying to enhance the effect of cleaning. With reference to FIG. 2D, in the step of chemical spraying, the chemical spraying solution 140 is used to spray the exposed surface of the carrier film 112, wherein the chemical spraying solution 140 comprises the material of conventional negative photoresist developer or positive photoresist cleaning liquid with a thinner concentration, such as asxylene, PGME, or DI water. Thereby, the particles 115 come from the outside during the process, the particles 115 and the residual photoresist 114 stuck on the carrier film 112, as well as the dry film burrs 116 on the lateral margin of the photoresist layer 111 are all removed through the cleaning step. Furthermore, under the protection of the carrier film 112, the photoresist layer 111 is not removed excessively. Subsequently, with reference to FIG. 2E, in the step of rinsing through the DI water, a DI water 150 is used to spray the exposed surface of the carrier film 112, thereby continuously removing the particles 115, the residual chemical spraying solution 140, and the dissolved or loosened residual photoresist 114. When the chemical spraying solution 140 is a DI water, i.e., it may dissolve the residual photoresist 114, the step of chemical spraying and the step of rinsing may be integrated into one single step. Then, with reference to FIG. 2F, in the step of drying, a dry gas 160, such as nitrogen gas, is provided to remove the DI water 150 and continuously remove the particles 115, thereby greatly enhancing the cleanliness of the exposed surface of the carrier film 112. Furthermore, after the step of the whole cleaning, a lateral shrinkage 111a is formed in the photoresist layer 111 and used to determine whether or not the photoresist layer 111 has been cleaned and the cleaning effect.

Next, with reference to FIG. 2G, a step of exposing is performed. Generally, the cleaned wafer 120, the photoresist layer 111 of the dry film 100, and the carrier film 112 with light transmission are placed in a yellow room to be exposed. A mask 170 is disposed above the carrier film 112, an exposure beam 171 passes through the mask 170 and then the carrier film 112, and finally irradiates and patterns the photoresist layer 111, such that the photoresist layer 111 has appropriate exposed zones 111B and unexposed zones 111C of an appropriate image. The exposed zones 111B represent the photochemical reaction has occurred on the photoresist layer 111. Preferably, the yellow room in the step of exposing is the same with the darkroom for cleaning the carrier film 112, thereby facilitating the continuity of the operation.

Subsequently, with reference to FIG. 2H, the carrier film 112 is removed and the photoresist layer 111 is developed, thereby forming a pattern. Since the photoresist layer 111 is the negative photoresist, the photoresist in the unexposed zones 111C is removed to form patterned recess regions 111D, thereby forming or etching sequent bumps and circuits. Therefore, with the method for utilizing a dry film provided by the present invention, the carrier film 112 of the dry film 100 and the wafer 120 are cleaned sufficiently for achieving the accurate exposure, thereby forming correct patterned recess regions 111D. When the exposure tests of dry films are performed on the same batch of wafers, the low yield of the conventional operation flow is 0.58%, and with the method for utilizing a dry film provided by the present invention, the low yield of the processed wafers is effectively reduced to 0.01%. Thus, the process is improved significantly. The method for utilizing a dry film provided by the present invention is used to manufacture bumps during a wafer level packaging process, such that the formed bumps in sequent have the same shape and size.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method for forming a photoresist on a wafer, comprising:
providing a wafer with an active area;
forming at least one photoresist layer on the active area of the wafer;
forming a carrier film with light transmission on the photoresist layer; and
cleaning the carrier film and the wafer.

2. The method for forming a photoresist on a wafer as claimed in claim 1, wherein the step of cleaning the carrier film further comprises:
performing a step of chemical solution spraying for removing the residual photoresist and particles on the carrier film;
performing a step of rinsing through de-ionized (DI) water for removing the chemical solution; and
performing a step of drying for removing the DI water by employing a gas.

3. The method for forming a photoresist on a wafer as claimed in claim 2, wherein in the step of drying, the employed gas is nitrogen gas.

4. The method for forming a photoresist on a wafer as claimed in claim 1, further comprising exposing the photoresist layer through the carrier film.

5. The method for forming a photoresist on a wafer as claimed in claim 4, further comprising removing the carrier film and developing the photoresist layer.

6. The method for forming a photoresist on a wafer as claimed in claim 2, wherein in the steps of chemical spraying, rinsing through DI water, and drying, the wafer is placed in a darkroom or a yellow room.
